(19) United States
(12) Patent Application Publication
(10) Pub. No.: US 2025/0038041 A1
(43) Pub. Date: Jan. 30, 2025

(54) CERAMIC SUSCEPTOR

(71) Applicant: NGK INSULATORS, LTD., Nagoya-City (JP)

(72) Inventors: Yutaka UNNO, Handa-Shi (JP); Reon TAKANOYA, Handa-Shi (JP)

(73) Assignee: NGK INSULATORS, LTD., Nagoya-City (JP)

(21) Appl. No.: 18/675,226

(22) Filed: May 28, 2024

Related U.S. Application Data
(63) Continuation of application No. PCT/JP2023/027827, filed on Jul. 28, 2023.

(51) Int. Cl. H01L 21/687

(52) U.S. Cl. CPC H01L 21/68785; H01L 21/68757; H01L 21/68792

(57) ABSTRACT

There is provided a ceramic susceptor including a ceramic plate bonded body including a first ceramic plate and a second ceramic plate; an internal electrode embedded in the first ceramic plate; a terminal hole provided to penetrate the second ceramic plate in a thickness direction so as to reach the internal electrode and the like, the terminal hole including a small-diameter portion and a large-diameter portion, the small-diameter portion closer to a bottom of the terminal hole, the large-diameter portion far from the bottom of the terminal hole; an eyelet made of metal and adapted to be fitted in the small-diameter portion; a terminal rod inserted through the terminal hole and the eyelet, the terminal rod having one end connected to the internal electrode; and an isolation structure including a space and/or an insulating material for electrically isolating the terminal rod and the eyelet from the ceramic bonding interface.

### CROSS-REFERENCE TO RELATED APPLICATION

This application is a continuation application of PCT/JP2023/027827 filed Jul. 28, 2023, the entire contents of which are incorporated herein by reference.

### BACKGROUND OF THE INVENTION

### 1. Field of the Invention

The present disclosure relates to a ceramic susceptor.

### 2. Description of the Related Art

A susceptor for supporting a wafer is used in a film-deposition system or an etching system for a semiconductor production process. As such a susceptor, a susceptor is widely used that includes a ceramic plate for placing a wafer thereon, and a cylindrical ceramic shaft attached to the ceramic plate. A ceramic plate typically has a structure in which an internal electrode, such as a heater electrode, an RF electrode, or an electrostatic chuck (ESC) electrode, is embedded in a ceramic substrate formed of aluminum nitride (AlN) that is excellent in both heat resistance and corrosion resistance, for example.

As a ceramic susceptor having an embedded internal electrode, a ceramic susceptor having an internal space, such as gas channels, is known. For example, Patent Literature 1 (JP2017-527984A) describes a substrate support including a first plate, which has a plurality of purge gas channels on its backside, a second plate disposed beneath the first plate, and an edge ring surrounding the first plate, in which the plurality of purge gas channels extend from a single inlet in the central portion of the first plate to a plurality of outlets of the peripheral portion of the first plate. In such a substrate support, the second plate includes a plurality of heating elements embedded therein to provide a plurality of heating zones.

As disclosed in Patent Literature 1, an internal space with a complex shape, such as those of the gas channels, can be formed by bonding together a plurality of ceramic substrates that include ceramic substrates having grooves or holes formed therein. In this point, a bonding agent that is suitable for bonding ceramic substrates together is known. For example, as a bonding agent for bonding together a plurality of substrates made of aluminum nitride ceramic, Patent Literature 2 (JP 2004-345952A) discloses a bonding agent containing a flux with the composition of CaO: 25 to 45 weight % and Y₂O₃: 5 to 30 weight %, with the balance being Al₂O₃, and also containing aluminum nitride ceramic.

Incidentally, a ceramic susceptor including an internal electrode is provided with a terminal hole for connecting a terminal rod to the internal electrode. Various proposals have been made to improve such a terminal hole. For example, Patent Literature 3 (JP2020-516043A) discloses a ceramic heater including a ceramic plate, which includes an embedded heating element, a thread formed on a part of the inner circumferential surface of an opening portion, and a connector embedded to be partially exposed from the bottom surface of the opening portion, and a support eyelet fastened through the thread and coupled to an electrode rod. Patent Literature 3 also discloses, from the perspective of alleviating stress, that the ceramic plate includes a concave portion formed to be recessed inward from the inner circumferential surface of the opening portion along an edge of the bottom surface, and that the concave portion is machined into a predetermined round shape.

### CITATION LIST

### Patent Literature

Patent Literature 1: JP2017-527984A
Patent Literature 2: JP2004-345952A
Patent Literature 3: JP2020-516043A

### SUMMARY OF THE INVENTION

As described above, a ceramic susceptor, which is obtained by forming internal channels, such as gas channels, between ceramic plates by bonding ceramic substrates together, and also embedding an internal electrode (i.e., a heater electrode, an RF electrode, an ESC electrode, or the like) therein, is known. To produce such a ceramic susceptor, the ceramic substrates are bonded together first, and then, machining is performed to form a terminal hole for the electrical connection to the internal electrode. After that, a terminal rod is inserted through the terminal hole via an eyelet made of metal, and is bonded to the internal electrode by brazing, for example, so that electrical connection between the terminal rod and the internal electrode is established. However, there is a problem in that insulation resistance between the internal electrode as well as the terminal rod connected thereto and the surface of the ceramic susceptor would decrease (such insulation resistance is measured under water, and thus may be hereinafter referred to as “underwater insulation resistance”). Such a decrease in the underwater insulation resistance would undesirably increase the risk of causing abnormalities in a semiconductor production process, such as film deposition, etching, and ion implantation, that involves the use of the ceramic susceptor.

The inventors have found that providing a ceramic susceptor, which includes a terminal rod and an eyelet in its terminal hole, with a structure that allows the terminal rod and the eyelet to be electrically isolated from the ceramic bonding interface can achieve high underwater insulation resistance between the surface of the ceramic susceptor and the internal electrode as well as the terminal rod connected thereto.

Thus, an object of the present invention is to provide a ceramic susceptor that includes an eyelet and a terminal rod in its a terminal hole, and also includes an internal electrode within a ceramic plate bonded body, and that can achieve high underwater insulation resistance between the surface of the ceramic susceptor and the internal electrode as well as the terminal rod connected thereto.

The present disclosure provides the following aspects.

### [Aspect 1]

A ceramic susceptor comprising:
a ceramic plate bonded body including a first ceramic plate and a second ceramic plate that are bonded together via a ceramic bonding interface, and having a first face on the first ceramic plate side and a second face on the second ceramic plate side;
at least one internal electrode embedded in the first ceramic plate, the at least one internal electrode being selected from the group consisting of a heater electrode, an RF electrode, and an ESC electrode;
a terminal hole provided to penetrate the second ceramic plate and cross the ceramic bonding interface in a thickness direction from the second face of the second ceramic plate so as to reach the internal electrode in the first ceramic plate or a metal member connected to the internal electrode, the terminal hole including a small-diameter portion and a large-diameter portion, the small-diameter portion forming a side closer to a bottom of the terminal hole and having a relatively small hole diameter, the large-diameter portion forming a side far from the bottom of the terminal hole and having a relatively large hole diameter;
an eyelet made of metal, the eyelet being adapted to be fitted in the small-diameter portion of the terminal hole;
a terminal rod inserted through the terminal hole and the eyelet in the terminal hole, the terminal rod having one end directly or indirectly connected to the internal electrode, and having another end extending to an outside of the ceramic plate bonded body from the second face; and
an isolation structure including a space and/or an insulating material for electrically isolating the terminal rod and the eyelet from the ceramic bonding interface.

### [Aspect 2]

The ceramic susceptor according to aspect 1, further comprising an internal channel provided in the first ceramic plate and/or in the second ceramic plate such that the internal channel faces the ceramic bonding interface.

### [Aspect 3]

The ceramic susceptor according to aspect 2, wherein the internal channel is at least one selected from the group consisting of a gas channel, a cooling medium channel, a vacuuming channel, and a groove for inserting a thermocouple.

### [Aspect 4]

The ceramic susceptor according to any one of aspects 1 to 3,
wherein the eyelet extends in a direction of a center axis of the terminal hole up to a height corresponding to the second ceramic plate beyond a height position of the ceramic bonding interface, and the large-diameter portion extends to an inside of the first ceramic plate beyond the height position of the ceramic bonding interface, and
wherein the isolation structure includes a space formed between an inner wall surface of the large-diameter portion and the eyelet.

### [Aspect 5]

The ceramic susceptor according to aspect 4, further comprising an insulating tube covering the inner wall surface of the large-diameter portion, whereby the insulating tube covers an end portion of the ceramic bonding interface, and thus partially forms the isolation structure.

### [Aspect 6]

The ceramic susceptor according to any one of aspects 1 to 5,
wherein the eyelet extends in a direction of a center axis of the terminal hole up to a height corresponding to the second ceramic plate beyond a height position of the ceramic bonding interface, and the large-diameter portion is terminated within the second ceramic plate without reaching the ceramic bonding interface, and
wherein the isolation structure includes a space formed between the eyelet and the ceramic bonding interface.

### [Aspect 7]

The ceramic susceptor according to any one of aspects 1 to 6,
wherein the eyelet is terminated within the first ceramic plate without reaching a height position of the ceramic bonding interface, and the large-diameter portion is terminated within the second ceramic plate without reaching the height position of the ceramic bonding interface, and
wherein the isolation structure includes a gap formed between the terminal rod and an inner wall of the small-diameter portion as the eyelet within the small-diameter portion does not reach the height position of the ceramic bonding interface.

### [Aspect 8]

The ceramic susceptor according to aspect 7, further comprising an insulating tube covering an inner wall surface of the small-diameter portion, whereby the insulating tube covers an end portion of the ceramic bonding interface, and thus partially forms the isolation structure.

### [Aspect 9]

The ceramic susceptor according to any one of aspects 1 to 8, further comprising an insulating film covering an outer peripheral surface of the eyelet, whereby the insulating film covers an end portion of the ceramic bonding interface, and thus partially forms the isolation structure.

### [Aspect 10]

The ceramic susceptor according to any one of aspects 1 to 9, further comprising a cylindrical ceramic shaft attached to the second face, the cylindrical ceramic shaft including an internal space.

### [Aspect 11]

The ceramic susceptor according to any one of aspects 1 to 10, wherein each of the first ceramic plate and the second ceramic plate includes aluminum nitride or aluminum oxide.

### [Aspect 12]

The ceramic susceptor according to any one of aspects 1 to 11, wherein the first ceramic plate and the second ceramic plate are composed of materials with the same physical properties.

### [Aspect 13]

The ceramic susceptor according to any one of aspects 1 to 12, wherein the first ceramic plate and the second ceramic plate are composed of materials with different physical properties.

### BRIEF DESCRIPTION OF THE DRAWINGS

FIG. 1 is a schematic cross-sectional view illustrating an example of a ceramic susceptor according to the present invention.

FIG. 2 is a schematic cross-sectional view illustrating an example of a structure around a terminal hole of the ceramic susceptor illustrated in FIG. 1.

FIG. 3 is a schematic cross-sectional view illustrating another example of the structure around the terminal hole of the ceramic susceptor according to the present invention.

FIG. 4 is a schematic cross-sectional view illustrating another example of the structure around the terminal hole of the ceramic susceptor according to the present invention.

FIG. 5 is a schematic cross-sectional view illustrating another example of the structure around the terminal hole of the ceramic susceptor according to the present invention.

FIG. 6 is a schematic cross-sectional view illustrating another example of the structure around the terminal hole of the ceramic susceptor according to the present invention.

FIG. 7 is a schematic cross-sectional view illustrating another example of the ceramic susceptor according to the present invention.

FIG. 8 is a schematic cross-sectional view illustrating an example of a structure around a terminal hole of the ceramic susceptor illustrated in FIG. 7.

FIG. 9 is a conceptual view illustrating a measuring system for measuring the underwater insulation resistance of a ceramic susceptor.

FIG. 10 is a schematic cross-sectional view illustrating an example of a structure around a terminal hole of a ceramic susceptor according to a comparative aspect.

### DETAILED DESCRIPTION OF THE INVENTION

A ceramic susceptor according to the present invention is a ceramic base for supporting a wafer for use in a film-deposition system or an etching system, in particular, in a film-deposition system or an etching system for a semiconductor production process. For example, the ceramic susceptor according to the present invention may be a ceramic heater for a semiconductor film-deposition system, or an electrostatic chuck for a semiconductor etching system. Alternatively, the ceramic susceptor according to the present invention may be an electrostatic chuck heater that has both the functions of a heater and an electrostatic chuck. Typical examples of the film-deposition system include a CVD (chemical vapor deposition) system (e.g., a thermal CVD system, a plasma CVD system, an optical CVD system, or a MOCVD system) and a PVD (physical vapor deposition) system.

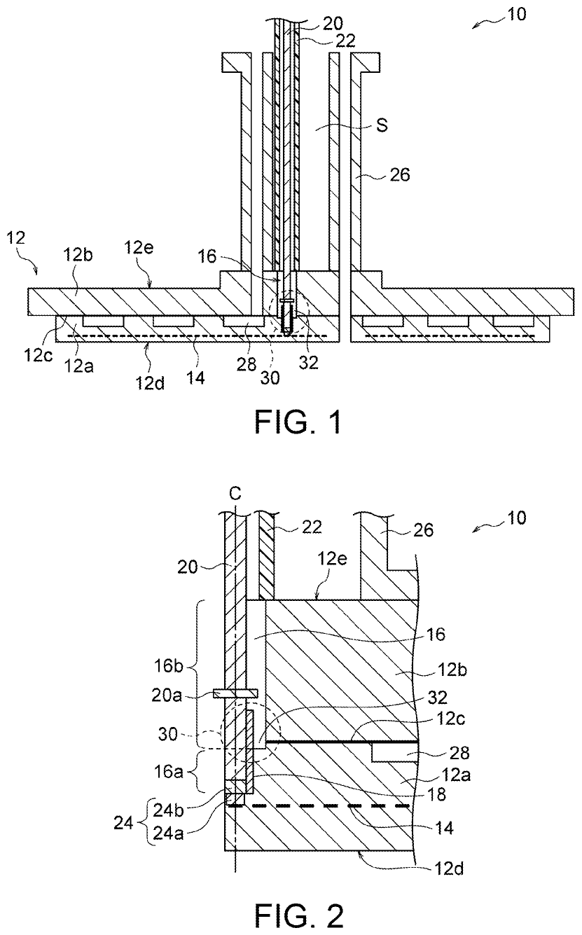

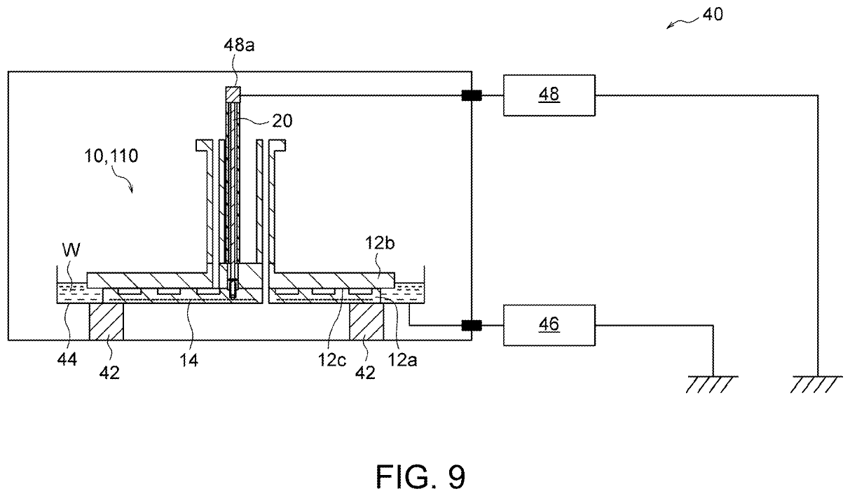

FIGS. 1 and 2 illustrate an aspect of the ceramic susceptor. Note that throughout all drawings including FIGS. 1 and 2, a ceramic susceptor 10 is illustrated as being oriented during production or during the measurement of underwater insulation resistance (see FIG. 9) for the sake of convenience of description, and thus is illustrated as being oriented opposite to its orientation during use in a semiconductor production system (i.e., illustrated upside down). The ceramic susceptor 10 illustrated in FIGS. 1 and 2 includes a ceramic plate bonded body 12, an internal electrode 14, a terminal hole 16, an eyelet 18, a terminal rod 20, and an isolation structure 30. The ceramic plate bonded body 12 includes a first ceramic plate 12a and a second ceramic plate 12b that are bonded together via a ceramic bonding interface 12c. The ceramic plate bonded body 12 includes a first face 12d on the first ceramic plate 12a side and a second face 12e on the second ceramic plate 12b side. The first ceramic plate 12a has the internal electrode 14 embedded herein. The internal electrode 14 includes at least one electrode selected from the group consisting of a heater electrode, an RF electrode, and an ESC electrode. The terminal hole 16 is provided to penetrate the second ceramic plate 12b and cross the ceramic bonding interface 12c in the thickness direction from the second face 12e of the second ceramic plate 12b so as to reach the internal electrode 14 in the first ceramic plate 12a or a metal member 24 connected to the internal electrode 14. The terminal hole 16 includes, as illustrated in FIG. 2, a small-diameter portion 16a that forms a side closer to the bottom (i.e., the closed end) of the terminal hole and has a relatively small hole diameter, and a large-diameter portion 16b that forms a side far from the bottom of the terminal hole 16 and has a relatively large hole diameter. The eyelet 18 is a metal cylindrical member fitted in the small-diameter portion 16a of the terminal hole 16. The terminal rod 20 is inserted through the terminal hole 16 and the eyelet 18 therein. One end of the terminal rod 20 is directly or indirectly connected to the internal electrode 14, and the other end of the terminal rod 20 extends to the outside of the ceramic plate bonded body 12 from the second face 12e. The isolation structure 30 includes a space and/or an insulating material that allow(s) the terminal rod 20 and the eyelet 18 to be electrically isolated from the ceramic bonding interface 12c. In this manner, as the ceramic susceptor 10, which includes the terminal rod 20 and the eyelet 18 in its terminal hole 16, is provided with a structure that allows the terminal rod 20 and the eyelet 18 to be electrically isolated from the ceramic bonding interface 12c, it is possible to achieve high underwater insulation resistance between the surface of the ceramic susceptor 10 and the internal electrode 14 as well as the terminal rod 20 connected thereto.

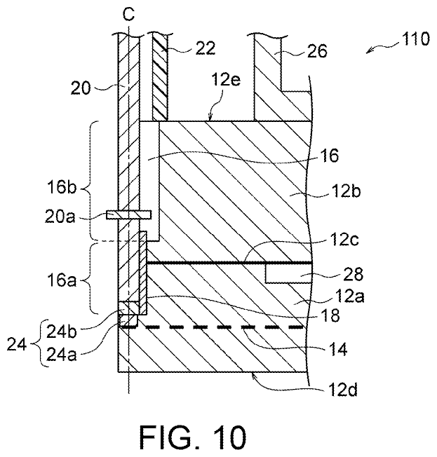

As described above, a ceramic susceptor, which is obtained by forming internal channels, such as gas channels, between ceramic plates by bonding ceramic substrates together, is known. However, such a conventional configuration has a problem in that the underwater insulation resistance between the internal electrode as well as the terminal rod connected thereto and the surface of the ceramic susceptor would decrease. Such a decrease in the underwater insulation resistance would undesirably increase the risk of causing abnormalities in a semiconductor production process, such as film deposition, etching, and ion implantation, that involves the use of the ceramic susceptor. It has been found through the investigation of the inventors that such a decrease in the underwater insulation resistance occurs at a portion where the bonding interface between the ceramic plates is in contact with the structure of the electrode terminal (i.e., a metal part like the eyelet or the terminal rod). In particular, since the ceramic bonding interface 12c supposed in the present invention is not a metal interface, it is usually not predicted that the interface that is exposed will impair the insulating property. However, to the contrary, the inventors have found that the ceramic bonding interface 12c causes a decrease in the insulation resistance. Although a mechanism for estimating a decrease in the insulation resistance at the ceramic bonding portion is not certain, it is considered that a ceramic-based bonding agent such as the one disclosed in Patent Literature 2 is related thereto. That is, as in a ceramic susceptor 110 according to a comparative aspect illustrated in FIG. 10, when the ceramic plate bonded body 12 having the ceramic bonding interface 12c, which is derived from a ceramic-based bonding agent, is machined to form the terminal hole 16 for electrical connection, the ceramic bonding interface 12c is exposed in the terminal hole 16 obtained through the machining. Thus, it is estimated that components derived from the ceramic-based bonding agent that has been fired function to impair the insulating property. Specifically, it is estimated that as the constituents of the bonding agent exposed from the ceramic bonding interface 12c are incorporated into the terminal hole 16, and then come into contact with a metal part (i.e., the eyelet 18, the terminal rod 20, the metal member 24, and the like) that is directly or indirectly bonded to the internal electrode 14 by brazing, a significant decrease in the insulation resistance occurs. Thus, as illustrated in FIG. 2, providing a structure (i.e., the isolation structure 30) that allows the ceramic bonding interface 12c, which is the bonding portion of the ceramic plates 12a and 12b, to be not in direct contact with the internal electrode 14 as well as the terminal rod 20 connected thereto can prevent the foregoing decrease in the underwater insulation resistance. Thus, a ceramic susceptor with high underwater insulation resistance can be provided.

The ceramic plate bonded body 12 includes the first ceramic plate 12a and the second ceramic plate 12b. The first ceramic plate 12a and the second ceramic plate 12b may be composed of materials with either the same physical properties or different physical properties (e.g., volume resistance or coefficients of thermal expansion). In the latter case, for example, the volume resistance of the first ceramic plate 12a may be set relatively higher than the volume resistance of the second ceramic plate 12b, or the volume resistance of the second ceramic plate 12b may be set relatively higher than volume resistance of the first ceramic plate 12a. In any case, configurations other than those of the first ceramic plate 12a, the second ceramic plate 12b, and the isolation structure 30 are not limited to particular configurations, and configurations similar to those of ceramic plates adopted for a known ceramic susceptor or ceramic heater may be used. Thus, each of the first ceramic plate 12a and the second ceramic plate 12b preferably contains aluminum nitride or aluminum oxide, and more preferably, aluminum nitride from the perspectives of obtaining excellent thermal conductivity, high electrical insulation properties, thermal expansion properties close to those of silicon, and the like.

The ceramic plate bonded body 12 further includes, between the first ceramic plate 12a and the second ceramic plate 12b, the ceramic bonding interface 12c for bonding them together. The ceramic bonding interface 12c is an interface layer derived from the ceramic-based bonding agent used for bonding the first ceramic plate 12a and the second ceramic plate 12b together, and remains after the ceramic-based bonding agent is fired. The ceramic-based bonding agent is not limited to a particular bonding agent as long as it can be used for bonding the ceramic plates together. For example, the ceramic-based bonding agent may be a known ceramic-based bonding agent such as the one disclosed in Patent Literature 2. The preferable ceramic-based bonding agent may be the one containing a flux with the composition of CaO: 25 to 45 weight % and Y₂O₃: 5 to 30 weight %, with the balance being Al₂O₃, and also containing 10 to 90 weight % of aluminum nitride ceramic with respect to the bonding agent (see Patent Literature 2).

The ceramic plate bonded body 12 preferably has a disc shape. However, the disc-shaped ceramic plate bonded body 12 need not be in the shape of a complete circle as seen in plan view. For example, it may be in the shape of an incomplete circle having a partially missing part like an orientation flat. The size of the ceramic plate bonded body 12 may be determined as appropriate in accordance with the diameter of a wafer that is supposed to be used, and is not limited to a particular size. If the ceramic plate bonded body 12 is in the shape of a circle, its diameter is typically 150 to 450 mm, and for example, about 300 mm. In addition, as illustrated in FIG. 1, the first ceramic plate 12a and the second ceramic plate 12b may have different diameters.

Optionally, a ceramic shaft 26 may be attached to the second face 12e of the ceramic plate bonded body 12. The ceramic shaft 26 is a cylindrical member including an internal space S, and may have a configuration similar to that of a ceramic shaft adopted for a known ceramic susceptor or ceramic heater. The internal space S is configured to allow the terminal rod 20 to pass therethrough. The ceramic shaft 26 is preferably formed of a ceramic material similar to that of the ceramic plate bonded body 12. Thus, the ceramic shaft 26 preferably contains aluminum nitride or aluminum oxide, and more preferably contains aluminum nitride. The upper end face of the ceramic shaft 26 is preferably solid-phase bonded or diffusion-bonded to the second face 12e of the ceramic plate bonded body 12. The outside diameter of the ceramic shaft 26 is not limited to a particular value, and is about 40 mm, for example. The inside diameter (i.e., the diameter of the internal space S) of the ceramic shaft 26 is not limited to a particular value, either, and is about 36 mm, for example.

The internal electrode 14 is an electrode embedded in the first ceramic plate 12a, and includes at least one electrode selected from the group consisting of a heater electrode, an RF electrode, and an ESC electrode. The heater electrode is not limited to a particular electrode, but may be an electrically conductive coil wired over the entire surface of the first ceramic plate 12a like a unicursal pattern, for example. The terminal rod 20 is connected to the opposite ends of the heater electrode to feed power thereto, and the terminal rod 20 is connected to a heater power supply (not illustrated). The heater electrode generates heat when supplied with power from the heater power supply, and heats a wafer placed on the surface of the first ceramic plate 12a. The heater electrode is not limited to a coil, and may be a ribbon (i.e., a thin elongated plate), a mesh, or a print, for example. The RF electrode allows for the deposition of a film with a plasma CVD process when high frequency is applied thereto. The ESC electrode is the abbreviation of an electrostatic chuck (ESC) electrode, and is also referred to as an electrostatic electrode. The ESC electrode is preferably a circular, thin-layer electrode with a diameter slightly smaller than that of the ceramic plate bonded body 12. For example, the ESC electrode may be a sheet-like mesh electrode formed by weaving a thin metal wire in a mesh pattern. The ESC electrode may also be used as a plasma electrode. That is, it is also possible to use the ESC electrode as an RF electrode by applying high frequency to the ESC electrode, and thus deposit a film with a plasma CVD process using the ESC electrode. The terminal rod 20 is connected to the ESC electrode to feed power thereto, and the terminal rod 20 is connected to an external power supply (not illustrated). The ESC electrode allows a wafer placed on the surface of the ceramic plate bonded body 12 to be chucked with the Johnsen-Rahbek force when a voltage is applied thereto from the external power supply. The internal electrode 14 preferably includes a heater electrode and an RF or ESC electrode. In addition, the internal electrode 14 may also be embedded within the second ceramic plate 12b.

Optionally, an internal channel 28 may be provided in the first ceramic plate 12a and/or in the second ceramic plate 12b such that it faces the ceramic bonding interface 12c. The internal channel 28 may be at least one selected from the group consisting of a gas channel, a cooling medium channel, a vacuuming channel, and a groove for inserting a thermocouple. Such an internal channel 28 tends to have a complex shape. Thus, it is preferable to form the internal channel 28 by forming in advance a groove-like or channel-like recess portion in the first ceramic plate 12a to form the internal channel 28 (in combination with the second ceramic plate 12b), and then bond the second ceramic plate 12b to a face of the first ceramic plate 12a having the recess portion formed therein, using a ceramic bonding agent. When the internal channel 28 is formed in the second ceramic plate 12b, the first ceramic plate 12a may be bonded on a face of the second ceramic plate 12b having a recess portion formed therein, using a ceramic bonding agent. When the internal channel 28 is formed in each of the first ceramic plate 12a and the second ceramic plate 12b, a face of the first ceramic plate 12a having a recess portion formed therein and a face of the second ceramic plate 12b having a recess portion formed therein may be bonded together, using a ceramic bonding agent. Thus, as illustrated in FIGS. 1 and 2, the internal channel 28 typically faces the ceramic bonding interface 12c. The presence of such an internal channel 28 facing the ceramic bonding interface 12c causes the ceramic bonding interface 12c to be exposed, and thus can become a cause for decreasing the underwater insulation resistance via the ceramic bonding interface 12c. However, according to the present invention, such a decrease in the underwater insulation resistance can be effectively prevented.

The terminal hole 16 is provided such that it penetrates the second ceramic plate 12b and crosses the ceramic bonding interface 12c in the thickness direction from the second face 12e so as to reach the internal electrode 14 in the first ceramic plate 12a or the metal member 24 connected to the internal electrode 14. The terminal hole 16 includes the small-diameter portion 16a that forms a side closer to the bottom (i.e., the closed end) of the terminal hole 16 and has a relatively small hole diameter, and the large-diameter portion 16b that forms a side far from the bottom of the terminal hole and has a relatively large hole diameter. The small-diameter portion 16a is a hole portion with a diameter that matches the eyelet 18 or the terminal rod 20 inserted therethrough, while the large-diameter portion 16b is designed to have a diameter greater than that of the small-diameter portion 16a, and thus is configured to allow a protruding portion 20a provided on the terminal rod 20 to enter the large-diameter portion 16b. Thus, the diameter of the large-diameter portion 16b is preferably greater than the diameter of the protruding portion 20a. For example, the diameter of the small-diameter portion 16a is 6 to 8 mm, and the diameter of the large-diameter portion 16b is 10 to 15 mm. In addition, the small-diameter portion 16a may be provided with an internal screw thread.

The eyelet 18 is a metal cylindrical member fitted in the small-diameter portion 16a of the terminal hole 16. The eyelet 18 serves the role of guiding the terminal rod 20 into the terminal hole 16 for smooth insertion. The eyelet 18 may be provided with a screw thread. In such a case, if the terminal rod 20 is also provided with a screw thread, it is possible to allow the terminal rod 20 to be threadably inserted through the eyelet 18. The metal for forming the eyelet 18 is not limited to a particular metal, but preferable examples of the metal include Ni, W, Mo, and a W—Mo alloy. Preferably, Ni is used. In addition, the outer periphery of the eyelet 18 may be provided with an external screw thread. Providing such a screw thread portion can allow the small-diameter portion 16a and the eyelet 18 to be threadably engaged with each other.

The terminal rod 20 is a rod-shaped feed member inserted through the terminal hole 16 and the eyelet 18 therein. The terminal rod 20 is provided such that one end thereof is directly or indirectly connected to the internal electrode 14, and the other end thereof extends to the outside of the ceramic plate bonded body 12 from the second face 12e. The phrase “directly or indirectly connected to the internal electrode 14” means that the terminal rod 20 may be directly connected to the internal electrode 14, or indirectly connected to the internal electrode 14 via the metal member 24. The tip end of the terminal rod 20 and the internal electrode 14 and/or the metal member 24 are preferably bonded together by brazing. The metal for forming the terminal rod 20 is not limited to a particular metal, but preferable examples of the metal include Ni, W, Mo, and a joint structure of Ni and W. Preferably, Ni is used. The terminal rod 20 may have the flanged protruding portion 20a along the outer periphery thereof at a predetermined position in the longitudinal direction (excluding its portion inserted through the small-diameter portion 16a). The protruding portion 20a is used as a portion to be contacted by the tip end of a loading jig (e.g., a ceramic tube) when the terminal rod 20 is inserted through the terminal hole 16 and is pushed toward the internal electrode 14 with a load applied thereto. The tip end of the terminal rod 20 is bonded to the internal electrode 14 and/or the metal member 24 by brazing. At this time, applying a load to the terminal rod 20 via the protruding portion 20a using the loading jig can allow the tip end of the terminal rod 20 to push the portions to be bonded together by brazing. Increasing the temperature in such a state up to the brazing temperature (e.g., about 1000° C.) can allow the terminal rod 20 and the metal member 24 (which correspond to the terminal rod 20 and a buffer material 24b and a tablet 24a in the example illustrated in the drawing) to be tightly bonded together by brazing.

Around the terminal rod 20, an insulating tube 22 is preferably provided to surround the outer peripheral face of the terminal rod 20. That is, the terminal rod 20 is preferably provided to pass through a hollow portion of the insulating tube 22. Accordingly, the insulating property around the terminal rod 20 is ensured. This can avoid, when more than one terminal rod 20 is present, electrical contact between the terminal rods 20.

The metal member 24 is a member provided between the internal electrode 14 and the terminal rod 20 to assist in securing the electrical connection therebetween. The configuration of the metal member 24 is not limited to a particular configuration. The metal member 24 preferably includes the tablet 24a and/or the buffer material 24b, and more preferably includes both the tablet 24a and the buffer material 24b. The tablet 24a is a lump metal member that helps secure the electrical connection with the internal electrode 14 (which is mesh-shaped, for example), and is provided on the internal electrode 14 side. Accordingly, it is possible to secure an area of contact that is sufficient to bond together the terminal rod 20 or the buffer material 24b and the internal electrode 14 by brazing. Preferable examples of the metal for forming the tablet 24a include Mo, W, and a W—Mo alloy. Preferably, Mo is used. The buffer material 24b is a metal member provided as a buffer for reducing the difference in thermal expansion between the tablet 24a and the terminal rod 20, and is provided between the tablet 24a and the terminal rod 20. Preferable examples of the metal for forming the buffer material 24b include alloys, such as Kovar® (i.e., an Fe—Ni—Co alloy). When the metal member 24 includes the tablet 24a and the buffer material 24b, it is preferable to bond the terminal rod 20, the buffer material 24b, and the tablet 24a to one another by brazing.

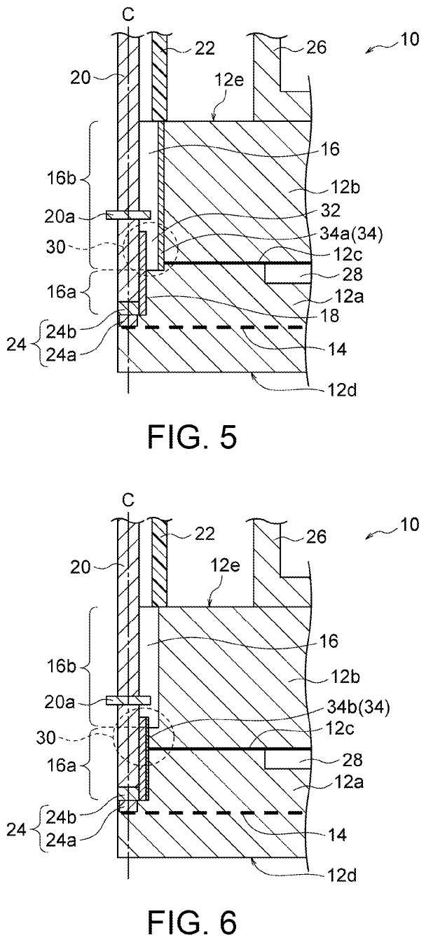

As illustrated in FIGS. 2 to 6 and 8, the isolation structure 30 includes a space 32 (see FIGS. 2 to 5 and 8) and/or an insulating material 34 (see FIGS. 5 and 6) for electrically isolating the terminal rod 20 and the eyelet 18 from the ceramic bonding interface 12c. In this manner, providing the isolation structure 30 for electrically isolating the terminal rod 20 and the eyelet 18 from the ceramic bonding interface 12c can achieve high underwater insulation resistance between the surface of the ceramic susceptor 10 and the internal electrode 14 as well as the terminal rod 20 connected thereto. Thus, the isolation structure 30 is not limited to a particular structure as long as it allows an end portion of the ceramic bonding interface 12c, which faces the terminal hole 16, to be not directly in contact with the terminal rod 20 or the eyelet 18 provided therearound.

According to a preferred aspect of the present invention, as illustrated in FIG. 2, the eyelet 18 extends in the direction of a central axis C of the terminal hole 16 up to the height corresponding to the second ceramic plate 12b beyond the height position of the ceramic bonding interface 12c, and also, the large-diameter portion 16b extends to the inside of the first ceramic plate 12a beyond the height position of the ceramic bonding interface 12c. Consequently, the isolation structure 30 includes the space 32 formed between the inner wall surface of the large-diameter portion 16b and the eyelet 18. This can avoid direct contact between the end portion of the ceramic bonding interface 12c and the eyelet 18 (and the terminal rod 20 therein). The space 32 according to the present aspect can be regarded as a portion partially forming the large-diameter portion 16b of the terminal hole 16.

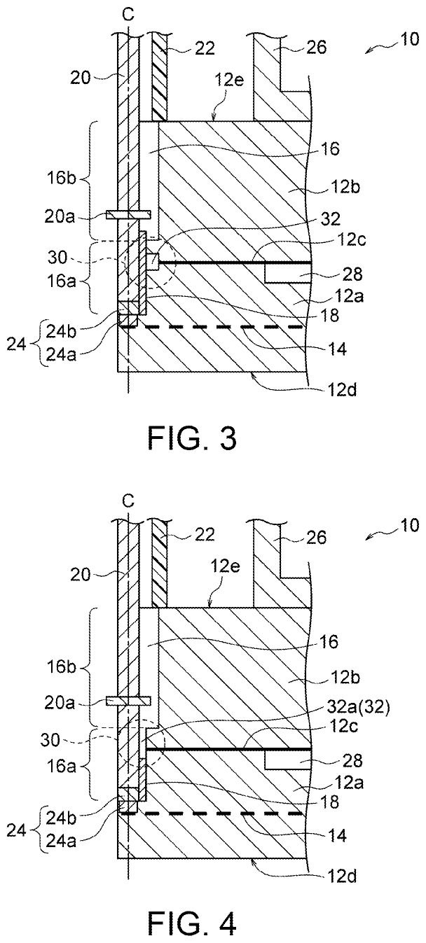

According to another preferred aspect of the present invention, as illustrated in FIG. 3, the eyelet 18 extends in the direction of the central axis C of the terminal hole 16 up to the height corresponding to the second ceramic plate 12b beyond the height position of the ceramic bonding interface 12c, and also, the large-diameter portion 16b is terminated within the second ceramic plate 12b without reaching the ceramic bonding interface 12c. Consequently, the isolation structure 30 includes the space 32 formed between the eyelet 18 and the ceramic bonding interface 12c. This can avoid direct contact between the end portion of the ceramic bonding interface 12c and the eyelet 18 (and the terminal rod 20 therein). The space 32 according to the present aspect can be regarded as an annular internal space provided around the annular eyelet 18.

According to another preferred aspect of the present invention, as illustrated in FIG. 4, the eyelet 18 is terminated within the first ceramic plate 12a without reaching the height position of the ceramic bonding interface 12c, and also, the large-diameter portion 16b is terminated within the second ceramic plate 12b without reaching the height position of the ceramic bonding interface 12c. Consequently, the isolation structure 30 includes a gap 32a formed between the terminal rod 20 and the inner wall of the small-diameter portion 16a as the eyelet 18 within the small-diameter portion 16a does not reach the height position of the ceramic bonding interface 12c. This can avoid direct contact between the end portion of the ceramic bonding interface 12c and the eyelet 18 (and the terminal rod 20 therein). The gap 32a (as the space 32) according to the present aspect can be regarded as a portion partially forming the small-diameter portion 16a of the terminal hole 16.

According to another preferred aspect of the present invention, as illustrated in FIG. 5, an insulating tube 34a covering the inner wall surface of the large-diameter portion 16b may be further provided. Such an insulating tube 34a covers an end portion of the ceramic bonding interface 12c, and thus can partially form the isolation structure 30. This can further effectively avoid direct contact between the end portion of the ceramic bonding interface 12c and the eyelet 18 (and the terminal rod 20 therein), and thus can stably ensure high underwater insulation resistance. The aspect illustrated in FIG. 5 corresponds to the one obtained by further providing the insulating tube 34a in the aspect illustrated in FIG. 2. However, the present aspect is not limited thereto. That is, the insulating tube 34a covering the inner wall surface of the large-diameter portion 16b may be combined with other aspects disclosed in this specification as appropriate.

According to another preferred aspect of the present invention, though not illustrated, an insulating tube (not illustrated) covering the inner wall surface of the small-diameter portion 16a may be further provided in the aspect illustrated in FIG. 4. Such an insulating tube covers an end portion of the ceramic bonding interface 12c, and thus can partially form the isolation structure 30. This can further effectively avoid direct contact between the end portion of the ceramic bonding interface 12c and the terminal rod 20, and thus can stably ensure high underwater insulation resistance. The present aspect corresponds to the one obtained by further providing an insulating tube in the aspect illustrated in FIG. 4. However, the present aspect is not limited thereto. That is, the insulating tube covering the inner wall surface of the small-diameter portion 16a may be combined with other aspects disclosed in this specification as appropriate.

According to a preferred aspect of the present invention, as illustrated in FIG. 6, an insulating film 34b covering the outer peripheral surface of the eyelet 18 may be further provided. Such an insulating film 34b covers an end portion of the ceramic bonding interface 12c, and thus can partially form the isolation structure 30. This can avoid direct contact between the end portion of the ceramic bonding interface 12c and the eyelet 18 (and the terminal rod 20 therein). The material for forming the insulating film 34b is not limited to a particular material as long as it is an insulating material. Preferable examples of the material include nitride, such as aluminum nitride, and an oxide film, such as yttrium oxide.

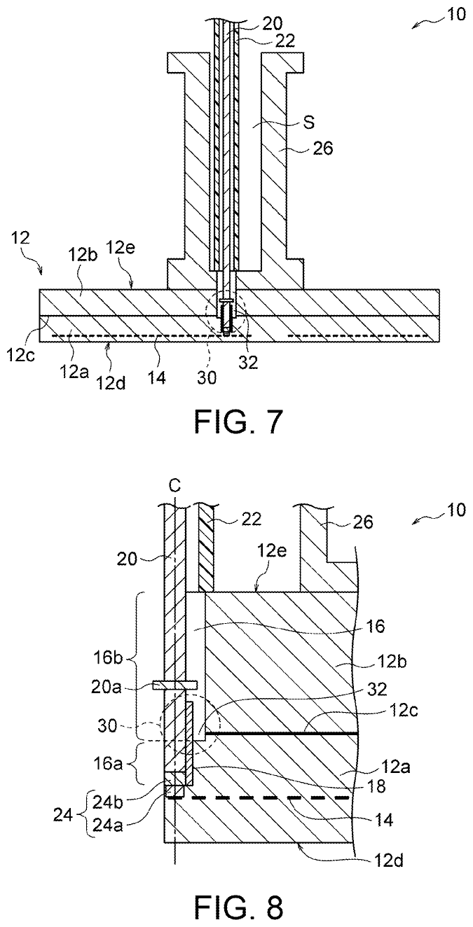

Each of the foregoing various aspects (see FIGS. 1 to 6) includes the internal channel 28. However, the ceramic susceptor of the present invention may be the one without the internal channel 28. FIGS. 7 and 8 illustrate an aspect of such a ceramic susceptor 10. The ceramic susceptor 10 illustrated in FIGS. 7 and 8 has a structure similar to that in FIG. 2 except that the internal channel 28 is not provided. Such a ceramic susceptor without the internal channel 28 also has a problem in that the underwater insulation resistance would decrease through the ceramic bonding interface 12c. However, such a problem can be solved by providing the isolation structure 30 (e.g., the space 32 formed between the inner wall surface of the large-diameter portion 16b and the eyelet 18 in the aspect illustrated in FIGS. 7 and 8). In addition, in such a ceramic susceptor 10 without an internal channel, the first ceramic plate 12a and the second ceramic plate 12b may also be composed of materials with either the same physical properties or different physical properties (e.g., volume resistance or coefficients of thermal expansion). In the latter case, for example, the volume resistance of the first ceramic plate 12a may be set relatively higher than the volume resistance of the second ceramic plate 12b, or the volume resistance of the second ceramic plate 12b may be set relatively higher than volume resistance of the first ceramic plate 12a.

Although various aspects have been described above, each component described with reference to the aspect illustrated in FIGS. 1 and 2 similarly applies to a corresponding component that is assigned the same reference sign in each of the aspects illustrated in FIGS. 3 to 8, excluding specific changed portions of the aspect.

### EXAMPLES

The present invention will be further specifically described by way of the following examples. However, the present invention is not limited to the following examples.

### Examples 1 to 8

### (1) Production of Ceramic Susceptors

Regarding the respective examples, various components illustrated in Table 1 were prepared. Using such components, the ceramic susceptors 10 and 110 with the specifications illustrated in Table 1 and with the various aspects illustrated in Table 2 as well as FIGS. 1 to 8 and 10 mentioned in Table 2 were produced in accordance with known procedures.

### [Table 1]

TABLE 1

| Components or | |
|---|---|
| Constituent | |
| Elements | Specifications |
| Ceramic Plate | Obtained by applying a ceramic-based bonding |
| Bonded body 12 | agent (i.e., the ceramic bonding interface 12c) |
| (Examples 1 to | to the faces to be bonded together of two |
| 5 and 7) | aluminum nitride sintered bodies (i.e., the |
| | first ceramic plate 12a and the second ceramic |
| | plate 12b) with the same physical property to |
| | bond them together, and then firing it at 1700 |
| | to 1850° C. for 3 hours under a nitrogen |
| | atmosphere. |
| First Ceramic | A disc-shaped aluminum nitride sintered body |
| Plate 12a | (with a thickness of 10 mm and a diameter of |
| (Examples 1 to | 360 mm) with the internal electrode 14 embedded |
| 5 and 7) | therein. It has a volume resistance of 100 GΩ |
| | (at room temperature), and has formed therein a |
| | groove for an internal flow channel. |
| Second Ceramic | A disc-shaped aluminum nitride sintered body |
| Plate 12b | (with a thickness of 14 mm and a diameter of |
| (Examples 1 to | 360 mm). It has a volume resistance of 100 GΩ |
| 5 and 7) | (at room temperature), and has the same physical |
| | property as the first ceramic plate 12a. |
| Ceramic Plate | Obtained by applying a ceramic-based bonding |
| Bonded body 12 | agent (i.e., the ceramic bonding interface 12c) |
| (Examples 6 | to the faces to be bonded together of two |
| and 8) | aluminum nitride sintered bodies (i.e., the |
| | first ceramic plate 12a and the second ceramic |
| | plate 12b) with different physical properties |
| | to bond them together, and then firing it at |
| | 1700 to 1850° C. for 3 hours under a nitrogen |
| | atmosphere. |
| First Ceramic | A disc-shaped aluminum nitride sintered body |
| Plate 12a | (with a thickness of 8 mm and a diameter of |
| (Examples 6 | 340 mm) with the internal electrode 14 embedded |
| and 8) | therein. It has a volume resistance of 100 GΩ |
| | (at room temperature), and has formed therein |
| | no groove for an internal flow channel. |
| Second Ceramic | A disc-shaped aluminum nitride sintered body |
| Plate 12b | (with a thickness of 10 mm and a diameter of |
| (Examples 6 | 340 mm). It has a volume resistance of 60 GΩ |
| and 8) | (at room temperature), and has a different |
| | physical property from the first ceramic plate |
| | 12a (i.e., has relatively low volume resistance). |
| Ceramic | A bonding interface formed using a ceramic- |
| Bonding | based bonding agent (with the composition in |
| interface 12c | the range described in paragraph [0016]) |
| | and having a thickness of 30 μm. |
| Internal | A mesh made of Mo and having a thickness of |
| Electrode | 700 μm. |
| 14 | Embedded in the first ceramic plate 12a. |
| Terminal | Includes the small-diameter portion 16a with |
| Hole 16 | an inside diameter of 7 mm and the large- |
| | diameter portion 16b with an inside diameter |
| | of 11 to 14 mm. |
| | The hole was formed by machining such that |
| | the respective lengths of the small-diameter |
| | portion 16a and the large-diameter portion |
| | 16b satisfy the positional relationship |
| | illustrated in each drawing |
| Eyelet 18 | A cylindrical member made of Ni. |
| Terminal | A rod-like member made of Ni including the |
| Rod 20 | main portion with a diameter of 4 mm and |
| | the protruding portion 20a with a diameter |
| | of 8 mm. |
| Tablet 24a | A disc-shaped member made of Mo. |
| Buffer | A disc-shaped member made of Kovar ®. |
| Material 24b | |
| Ceramic | A cylindrical aluminum nitride sintered body |
| Shaft 26 | (with a height of 173 mm, an outside diameter |
| | of 42 mm, and an inside diameter of 36 mm). |
| Insulating | A tube made of alumina. |
| Tube 34a | |
| Insulating | A coating made of yttria. |
| Film 34b | |

### (2) Measurement of Underwater Insulation Resistance

A measuring system 40 illustrated in FIG. 9 was assembled to measure the underwater insulation resistance of each of the produced ceramic susceptors 10 and 110 of the examples. The measuring system 40 includes an insulating base 42 made of an insulating material, a water tank 44 made of stainless steel and placed on the insulating base 42, an ammeter 46 (manufactured by Keithley Instruments) connected to the water tank 44, and a high-voltage power supply 48 (manufactured by Matsusada Precision Inc.). The ammeter 46 and the high-voltage power supply 48 are each connected to the ground. Ion-exchanged water W was put in the water tank 44, and as illustrated in FIG. 9, the ceramic susceptor 10 was placed in the water tank 44 such that the first ceramic plate 12a was completely immersed in the ion-exchanged water W and the water surface was located above the ceramic bonding interface 12c. The distal end of the terminal rod 20 was connected to the high-voltage power supply 48 via a connecting portion 48a. In such a state, the value of current was measured with the ammeter 46 while a voltage of 1 kV was applied to the terminal rod 20 by the high-voltage power supply 48. The underwater insulation resistance between the surface of the ceramic susceptor 10 and the terminal rod 20 connected to the internal electrode 14 was calculated by dividing the applied voltage (1 kV) by the value of current. Table 2 illustrates the results.

TABLE 2

| | | | Presence or Absence | |
|---|---|---|---|---|
| | | | of Contact Between | Underwater |
| | Corresponding | | Ceramic Plate Interface | Insulation |
| | Drawings | Structural Features | and Eyelet | Resistance |
| Example 1 | FIGS. 1 | A structure having the space 32 | Absent | Over 100 |
| | and 2 | formed by setting the depth of the | | GΩ |
| | | large-diameter portion 16b of the | | |
| | | terminal hole 16 to be beyond the | | |
| | | bonding interface 12c. | | |
| Example 2 | FIG. 3 | A structure having the space 32 | | |
| | | with a depth of about 1 mm formed | | |
| | | by machining the bonding interface | | |
| | | 12c and a region around it. | | |
| Example 3 | FIG. 4 | A structure having the gap 32a | | |
| | | formed by setting the length of | | |
| | | the eyelet 18 to be small. | | |
| Example 4 | FIG. 5 | A structure obtained by providing | | |
| | | the insulating tube 34a so as to | | |
| | | cover an end portion of the bonding | | |
| | | interface 12c in the structure of | | |
| | | Example 1 (FIG. 2). | | |
| Example 5 | FIG. 6 | A structure obtained by providing | | |
| | | the insulating film 34b so as | | |
| | | to cover an end portion of the | | |
| | | bonding interface 12c. | | |
| Example 6 | FIGS. 7 | A structure obtained by using | | |
| | and 8 | ceramic plates with different | | |
| | | physical properties that are | | |
| | | bonded together as the ceramic | | |
| | | plate bonded body 12, and | | |
| | | removing the internal channel | | |
| | | 28 in the structure of Example | | |
| | | 1 (FIG. 2). | | |
| Example | FIG. 10 | A structure without the | Present | Less than 10 |
| 7* | | isolation structure 30. | | MΩ |
| Example | FIG. 10 | A structure obtained by using | | |
| 8* | | ceramic plates with different | | |
| | | physical properties that are | | |
| | | bonded together as the ceramic | | |
| | | plate bonded body 12 in the | | |
| | | structure of Example 7. | | |

*represents comparative examples.

What is claimed is:

1. A ceramic susceptor comprising:
a ceramic plate bonded body including a first ceramic plate and a second ceramic plate that are bonded together via a ceramic bonding interface, and having a first face on the first ceramic plate side and a second face on the second ceramic plate side;
at least one internal electrode embedded in the first ceramic plate, the at least one internal electrode being selected from the group consisting of a heater electrode, an RF electrode, and an ESC electrode;
a terminal hole provided to penetrate the second ceramic plate and cross the ceramic bonding interface in a thickness direction from the second face of the second ceramic plate so as to reach the internal electrode in the first ceramic plate or a metal member connected to the internal electrode, the terminal hole including a small-diameter portion and a large-diameter portion, the small-diameter portion forming a side closer to a bottom of the terminal hole and having a relatively small hole diameter, the large-diameter portion forming a side far from the bottom of the terminal hole and having a relatively large hole diameter;
an eyelet made of metal, the eyelet being adapted to be fitted in the small-diameter portion of the terminal hole;
a terminal rod inserted through the terminal hole and the eyelet in the terminal hole, the terminal rod having one end directly or indirectly connected to the internal electrode, and having another end extending to an outside of the ceramic plate bonded body from the second face; and
an isolation structure including a space and/or an insulating material for electrically isolating the terminal rod and the eyelet from the ceramic bonding interface.

2. The ceramic susceptor according to claim 1, further comprising an internal channel provided in the first ceramic plate and/or in the second ceramic plate such that the internal channel faces the ceramic bonding interface.

3. The ceramic susceptor according to claim 2, wherein the internal channel is at least one selected from the group consisting of a gas channel, a cooling medium channel, a vacuuming channel, and a groove for inserting a thermocouple.

4. The ceramic susceptor according to claim 1,
wherein the eyelet extends in a direction of a center axis of the terminal hole up to a height corresponding to the second ceramic plate beyond a height position of the ceramic bonding interface, and the large-diameter portion extends to an inside of the first ceramic plate beyond the height position of the ceramic bonding interface, and
wherein the isolation structure includes a space formed between an inner wall surface of the large-diameter portion and the eyelet.

5. The ceramic susceptor according to claim 4, further comprising an insulating tube covering the inner wall surface of the large-diameter portion, whereby the insulating tube covers an end portion of the ceramic bonding interface, and thus partially forms the isolation structure.

6. The ceramic susceptor according to claim 1,
wherein the eyelet extends in a direction of a center axis of the terminal hole up to a height corresponding to the second ceramic plate beyond a height position of the ceramic bonding interface, and the large-diameter portion is terminated within the second ceramic plate without reaching the ceramic bonding interface, and
wherein the isolation structure includes a space formed between the eyelet and the ceramic bonding interface.

7. The ceramic susceptor according to claim 1,
wherein the eyelet is terminated within the first ceramic plate without reaching a height position of the ceramic bonding interface, and the large-diameter portion is terminated within the second ceramic plate without reaching the height position of the ceramic bonding interface, and
wherein the isolation structure includes a gap formed between the terminal rod and an inner wall of the small-diameter portion as the eyelet within the small-diameter portion does not reach the height position of the ceramic bonding interface.

8. The ceramic susceptor according to claim 7, further comprising an insulating tube covering an inner wall surface of the small-diameter portion, whereby the insulating tube covers an end portion of the ceramic bonding interface, and thus partially forms the isolation structure.

9. The ceramic susceptor according to claim 1, further comprising an insulating film covering an outer peripheral surface of the eyelet, whereby the insulating film covers an end portion of the ceramic bonding interface, and thus partially forms the isolation structure.

10. The ceramic susceptor according to claim 1, further comprising a cylindrical ceramic shaft attached to the second face, the cylindrical ceramic shaft including an internal space.

11. The ceramic susceptor according to claim 1, wherein each of the first ceramic plate and the second ceramic plate includes aluminum nitride or aluminum oxide.

12. The ceramic susceptor according to claim 1, wherein the first ceramic plate and the second ceramic plate are composed of materials with the same physical properties.

13. The ceramic susceptor according to claim 1, wherein the first ceramic plate and the second ceramic plate are composed of materials with different physical properties.
